(19) United States
(12) Patent Application Publication
(10) Pub. No.: US 2025/0149503 A1
(43) Pub. Date: May 8, 2025

(54) PACKAGE STRUCTURE

(71) Applicant: Unimicron Technology Corp., Taoyuan City (TW)

(72) Inventors: John Hon-Shing Lau, Taoyuan City (TW); Tzyy-Jang Tseng, Taoyuan City (TW)

(73) Assignee: Unimicron Technology Corp., Taoyuan City (TW)

(21) Appl. No.: 18/590,958

(22) Filed: Feb. 29, 2024

Related U.S. Application Data
(63) Continuation-in-part of application No. 18/503,194, filed on Nov. 7, 2023.

(51) Int. Cl. H01L 25/065; G02B 6/42; H01L 23/00; H01L 23/498

(52) U.S. Cl. CPC H01L 25/0652; G02B 6/4245; H01L 23/49816; H01L 23/49822; H01L 24/16; H01L 2224/16146; H01L 2224/16155; H01L 2924/01029; H01L 2924/1431; H01L 2924/1432; H01L 2924/1434; H01L 2924/15311; H01L 2924/182

(57) ABSTRACT

A package structure includes a package substrate, a system on a chip (SoC), at least one input/output circuit, multiple optoelectronic assemblies and an organic interposer. The SoC is disposed on the package substrate and includes a central processing unit (CPU), a graphics processing unit (GPU) and a memory. The input/output circuit is disposed on the package substrate. The optoelectronic assemblies are separately disposed on the package substrate and surround the SoC and the input/output circuit. The organic interposer is disposed on the package substrate. The SoC, the input/output circuit and the optoelectronic assemblies are electrically connected to the package substrate through the organic interposers.

### CROSS-REFERENCE TO RELATED APPLICATION

This application is a continuation-in-part application of and claims the priority benefit of U.S. application Ser. No. 18/503,194, filed on Nov. 7, 2023. The entirety of the above-mentioned patent application is hereby incorporated by reference herein and made a part of this specification.

### BACKGROUND

### Technical Field

The disclosure relates to a semiconductor structure, and in particular to a package structure.

### Description of Related Art

The existing application specific integrated circuit (ASIC) packages and integrates a central processing unit (CPU), a graphics processing unit (GPU), a memory and an input/output circuit into a system on a chip (SoC). Therefore, the volume of the SoC is very large. In addition, in terms of process technology, the CPU and the GPU need very fine feature sizes, such as less than 5 nanometers (nm), while the feature size of the input/output circuit is very large, such as 14 nm. This means that the needed process technology is different. Therefore, when the CPU, the GPU, the memory and the input/output circuit are packaged and integrated into the SoC, the yield is low and the cost is high.

### SUMMARY

The disclosure provides a package structure which may have low cost and high structural reliability.

The package structure of the disclosure includes a package substrate, a system on a chip (SoC), at least one input/output circuit, multiple optoelectronic assemblies and an organic interposer. The SoC is disposed on the package substrate and includes a central processing unit (CPU), a graphics processing unit (GPU) and a memory. The input/output circuit is disposed on the package substrate. The optoelectronic assemblies are separately disposed on the package substrate and surround the SoC and the input/output circuit. The organic interposer is fabricated separately and is disposed on the package substrate. The SoC, the input/output circuit and the optoelectronic assemblies are electrically connected to the package substrate through the organic interposer.

In an embodiment of the disclosure, the number of the above-mentioned input/output circuits is one. The input/output circuit is located next to a side of the SoC.

In an embodiment of the disclosure, the number of the above-mentioned input/output circuit is split into four. The input/output circuits are separated from each other, surround the SoC and are located between the SoC and the optoelectronic assemblies.

In an embodiment of the disclosure, each of the above-mentioned optoelectronic assemblies includes an electronic integrated circuit, a photonic integrated circuit and an encapsulant. The encapsulant covers the electronic integrated circuit and the photonic integrated circuit, and exposes a first bottom surface of the electronic integrated circuit and a second bottom surface of the photonic integrated circuit.

In an embodiment of the disclosure, each of the above-mentioned optoelectronic assemblies further includes an optical fiber cable, and the optical fiber cable is connected to the photonic integrated circuit.

In an embodiment of the disclosure, the above-mentioned package structure further includes multiple first conductive members, multiple second conductive members and multiple third conductive members. The first conductive members are disposed between the SoC and the organic interposer, and the SoC is electrically connected to the organic interposer through the first conductive members. The second conductive members are disposed between the input/output circuit and the organic interposer, and the input/output circuit is electrically connected to the organic interposer through the second conductive members. The third conductive members are disposed between the optoelectronic assemblies and the organic interposer, and the optoelectronic assemblies are electrically connected to the organic interposer through the third conductive members.

In an embodiment of the disclosure, each of the first conductive members, each of the second conductive members and each of the third conductive members respectively include a bump or a copper pillar with a solder bump cap.

In an embodiment of the disclosure, the above-mentioned package structure further includes multiple conductive members. The conductive members are disposed between the organic interposer and the package substrate, and the organic interposer is electrically connected to the package substrate through the conductive members.

In an embodiment of the disclosure, each of the above-mentioned conductive members includes a solder ball.

In an embodiment of the disclosure, the above-mentioned organic interposer includes a redistribution layer structure.

Based on the above, in the design of the package structure of the disclosure, the SoC including the CPU, the GPU and the memory and the input/output circuit are independent components. Therefore, compared with the existing technology, in which the CPU, the GPU, the memory and the input/output circuit are packaged and integrated into the SoC, the SoC of the disclosure may have a smaller volume, high yield and low cost, and thus the package structure of the disclosure may have low cost and high structural reliability.

In order to make the aforementioned features and advantages of the disclosure comprehensible, embodiments accompanied with drawings are described in detail as follows.

### BRIEF DESCRIPTION OF THE DRAWINGS

FIG. 1A is a schematic top view of a package structure according to an embodiment of the disclosure.

FIG. 1B is a schematic cross-sectional view along a line I-I of FIG. 1A.

FIG. 1C is a schematic cross-sectional view along a line II-II of FIG. 1A.

FIG. 2 is a schematic top view of a package structure according to another embodiment of the disclosure.

### DESCRIPTION OF THE EMBODIMENTS

Embodiments of the disclosure may be understood together with drawings, and the drawings of the disclosure are also regarded as a part of description of the disclosure. It should be understood that the drawings of the disclosure are not drawn to scale and, in fact, the dimensions of elements may be arbitrarily enlarged or reduced in order to clearly represent the features of the disclosure.

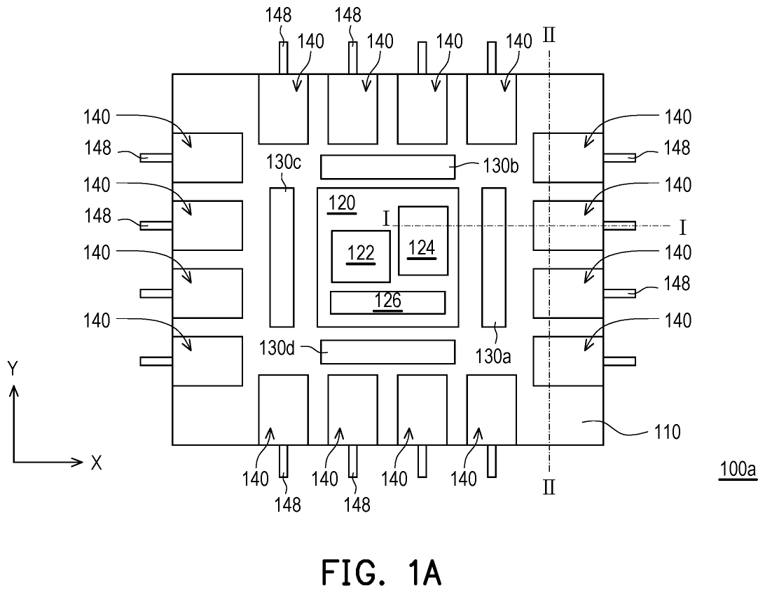

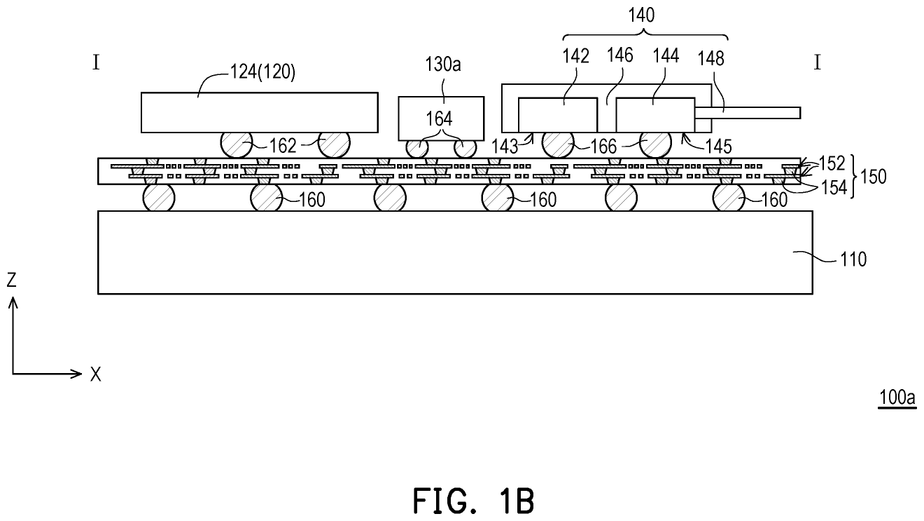

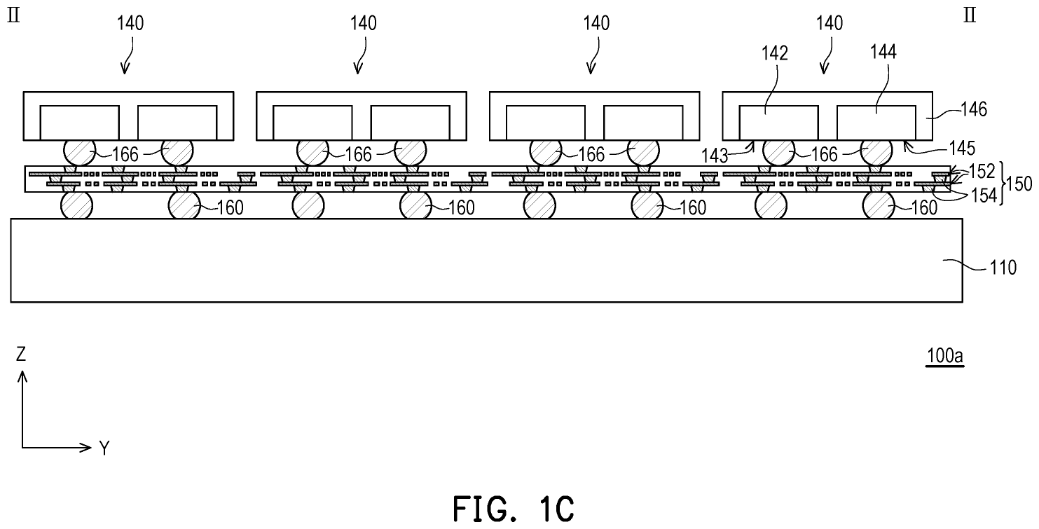

FIG. 1A is a schematic top view of a package structure according to an embodiment of the disclosure. FIG. 1B is a schematic cross-sectional view along a line I-I of FIG. 1A. FIG. 1C is a schematic cross-sectional view along a line II-II of FIG. 1A.

Please refer to FIGS. 1A, 1B and 1C at the same time. In the embodiment, a package structure 100a includes a package substrate 110, a system on a chip (SoC) 120, at least one input/output circuit (four input/output circuits 130a, 130b, 130c and 130d are schematically shown), multiple optoelectronic assemblies 140 and an organic interposer 150. The SoC 120 is disposed on the package substrate 110 and includes a central processing unit (CPU) 122, a graphics processing unit (GPU) 124 and a memory 126. The input/output circuits 130a, 130b, 130c and 130d are disposed on the package substrate 110, and located on organic interposer 150. The optoelectronic assemblies 140 are separately disposed on the package substrate 110, located on the organic interposer 150, and surround the SoC 120 and the input/output circuits 130a, 130b, 130c and 130d. The organic interposer 150 is separately fabricated and disposed on the package substrate 110. The SoC 120, the input/output circuits 130a, 130b, 130c and 130d and the optoelectronic assemblies 140 are electrically connected to the package substrate 110 through the organic interposer 150.

In detail, the input/output circuits 130a, 130b, 130c and 130d of the embodiment are separated from each other, surround the SoC 120 and are located between the SoC 120 and the optoelectronic assemblies 140. That is to say, the input/output circuits 130a, 130b, 130c and 130d and the SoC 120 in the embodiment are independent components. Since the SoC 120 of the embodiment does not include the input/output circuits 130a, 130b, 130c and 130d, compared with the existing technology, in which the CPU, the GPU, the memory and the input/output circuit are packaged and integrated into the SoC, the SoC 120 of the embodiment may have a smaller volume. Furthermore, since the input/output circuits 130a, 130b, 130c and 130d and the SoC 120 are independent components, the input/output circuits 130a, 130b, 130c and 130d and the SoC 120 may be formed using different process technology according to the feature sizes. Therefore, the SoC 120 of the embodiment may have higher yield and lower production cost. In addition, because the input/output circuits 130a, 130b, 130c and 130d are split from each other and surround the SoC 120, the transmission paths for the optoelectronic assemblies 140 to enter the SoC 120 through the input/output circuits 130a, 130b, 130c and 130d are shorter, which may effectively reduce parasitic capacitance.

In short, the embodiment separates a large-sized input/output circuit from a large-sized SoC in the existing technology so that the size of the SoC 120 may be smaller, and may effectively improve semiconductor manufacturing yield and effectively reduce manufacturing cost. In addition, splitting the large-sized input/output circuit into the four input/output circuits 130a, 130b, 130c and 130d may make semiconductor manufacturing yield higher and effectively reduce manufacturing cost.

Please refer to FIGS. 1B and 1C at the same time. Each of the optoelectronic assemblies 140 in the embodiment includes an electronic integrated circuit 142, a photonic integrated circuit 144 and an encapsulant 146. The encapsulant 146 covers the electronic integrated circuit 142 and the photonic integrated circuit 144, and exposes a first bottom surface 143 of the electronic integrated circuit 142 and a second bottom surface 145 of the photonic integrated circuit 144. In addition, each of the optoelectronic assemblies 140 further includes an optical fiber cable 148, and the optical fiber cable 148 is connected to the photonic integrated circuit 144.

Furthermore, the organic interposer 150 in the embodiment includes a redistribution layer structure. The redistribution layer structure includes multiple redistribution lines 152 and multiple conductive blind holes 154, and the redistribution lines 152 may be electrically connected to each other through the conductive blind holes 154. In an embodiment, the line width and line spacing of the redistribution lines 152 are, for example, 2 microns, which means that the redistribution lines 152 are fine line layers.

In addition, the package structure 100a of the embodiment further includes multiple conductive members 160, and the conductive members 160 are disposed between the organic interposer 150 and the package substrate 110. The organic interposer 150 is electrically connected to the package substrate 110 through the conductive members 160. In an embodiment, each of the conductive members 160 may be, for example, a solder ball. In addition, in the embodiment, the package structure 100a further includes multiple first conductive members 162, multiple second conductive members 164 and multiple third conductive members 166. The first conductive members 162 are disposed between the SoC 120 and the organic interposer 150, and the SoC 120 is electrically connected to the organic interposer 150 through the first conductive members 162. The second conductive members 164 are disposed between the input/output circuits 130a, 130b, 130c and 130d and the organic interposer 150, and the input/output circuits 130a, 130b, 130c and 130d are electrically connected to the organic interposer 150 through the second conductive members 164. The third conductive members 166 are disposed between the optoelectronic assemblies 140 and the organic interposer 150, and the optoelectronic assemblies 140 are electrically connected to the organic interposer 150 through the third conductive members 166. It should be noted that the forms of the first conductive member 162, the second conductive member 164, the third conductive member 166 and the organic interposer 150 are only shown as an example, even though the conductive member are not connected to the redistribution line or and the conductive blind hole of the organic interposer in the cross section shown in FIG. 1B and FIG. 1C, they may still be connected in other cross-sections not shown. In an embodiment, each of the first conductive members 162, each of the second conductive members 164 and each of the third conductive members 166 are each, for example, a bump or a copper pillar with a solder bump cap.

In short, since the SoC 120 including the CPU 122, the GPU 124 and the memory 126 and the input/output circuits 130a, 130b, 130c and 130d are independent components respectively, compared with the existing technology, in which the CPU, the GPU, the memory and the input/output circuit are packaged and integrated into the SoC, due to lack of the input/output circuits, the SoC 120 of the embodiment will have a smaller volume, high yield and lower cost, and thus, the package structure 100a of the embodiment may have low cost and high structural reliability.

Other embodiments are described below for illustrative purposes. It must be noted here that the following embodiments use the element numerals and part of the contents of the foregoing embodiments, the same numerals are used to denote the same or similar elements, and the description of the same technical content is omitted. For the description of the omitted parts, reference may be made to the foregoing embodiments, and thus the description is not repeated in the following embodiments.

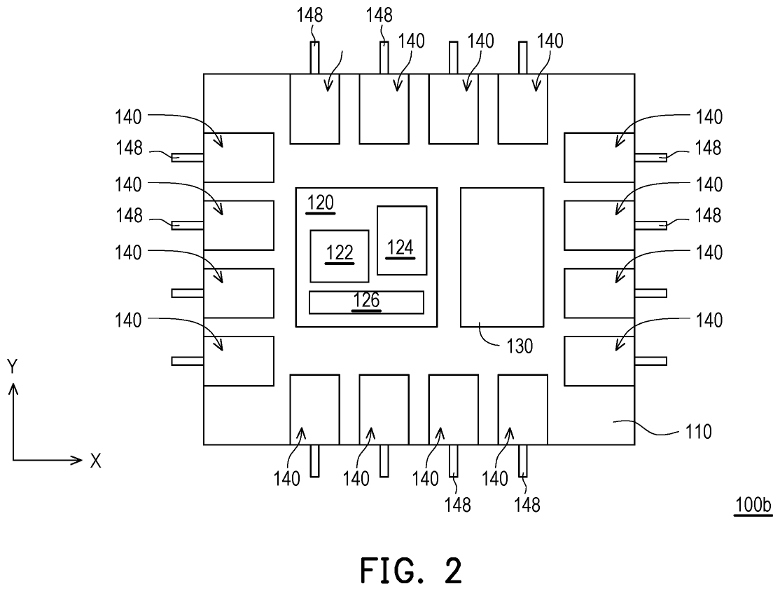

FIG. 2 is a schematic top view of a package structure according to another embodiment of the disclosure. Please refer to FIGS. 1A and 2 at the same time. A package substrate 100b of the embodiment is similar to the above-mentioned package substrate 100a. The main difference between the two is that in the embodiment, the number of input/output circuits 130 is merely one, and the input/output circuit 130 is located next to a side of the SoC 120. Since the embodiment separates a large-sized input/output circuit from a large-sized SoC in the existing technology so that the size of the SoC 120 may be smaller, and will effectively improve semiconductor manufacturing yield and effectively reduce manufacturing cost.

To sum up, in the design of the package structure of the disclosure, the SoC including the CPU, the GPU and the memory and the input/output circuit are independent components. Therefore, compared with the existing technology, in which the CPU, the GPU, the memory and the input/output circuit are packaged and integrated into the SoC, the SoC of the disclosure will have a smaller volume, high yield and low cost, and thus the package structure of the disclosure may have low cost and high structural reliability.

Although the disclosure has been described with reference to the above embodiments, the described embodiments are not intended to limit the disclosure. People of ordinary skill in the art may make some changes and modifications without departing from the spirit and the scope of the disclosure. Thus, the scope of the disclosure shall be subject to those defined by the attached claims.

What is claimed is:

1. A package structure, comprising:
a package substrate;
a system on a chip (SoC), disposed on the package substrate and comprising a central processing unit (CPU), a graphics processing unit (GPU) and a memory;
at least one input/output circuit, disposed on the package substrate;
a plurality of optoelectronic assemblies, separately disposed on the package substrate and surrounding the SoC and the at least one input/output circuit; and
an organic interposer, disposed on the package substrate, wherein the SoC, the at least one input/output circuit and the optoelectronic assemblies are electrically connected to the package substrate through the organic interposer.

2. The package structure according to claim 1, wherein the number of the at least one input/output circuits is one, and the input/output circuit is located next to a side of the SoC.

3. The package structure according to claim 1, wherein the number of the at least one input/output circuits is four, and the input/output circuits are separated from each other, surround the SoC and are located between the SoC and the optoelectronic assemblies.

4. The package structure according to claim 1, wherein each of the optoelectronic assemblies comprises an electronic integrated circuit, a photonic integrated circuit and an encapsulant, and the encapsulant covers the electronic integrated circuit and the photonic integrated circuit and exposes a first bottom surface of the electronic integrated circuit and a second bottom surface of the photonic integrated circuit.

5. The package structure according to claim 4, wherein each of the optoelectronic assemblies further comprises an optical fiber cable, and the optical fiber cable is connected to the photonic integrated circuit.

6. The package structure according to claim 1, further comprising:
a plurality of first conductive members, disposed between the SoC and the organic interposer, wherein the SoC is electrically connected to the organic interposer through the first conductive members;
a plurality of second conductive members, disposed between the at least one input/output circuit and the organic interposer, wherein the at least one input/output circuit is electrically connected to the organic interposer through the second conductive members; and
a plurality of third conductive members, disposed between the optoelectronic assemblies and the organic interposer, wherein the optoelectronic assemblies are electrically connected to the organic interposer through the third conductive members.

7. The package structure according to claim 6, wherein each of the first conductive members, each of the second conductive members and each of the third conductive members respectively comprise a bump or a copper pillar with a solder bump cap.

8. The package structure according to claim 1, further comprising:
a plurality of conductive members, disposed between the organic interposer and the package substrate, wherein the organic interposer is electrically connected to the package substrate through the conductive members.

9. The package structure according to claim 8, wherein each of the conductive members comprises a solder ball.

10. The package structure according to claim 1, wherein the organic interposer comprises a redistribution layer structure.
